(19) United States
(12) Patent Application Publication
(10) Pub. No.: US 2026/0023108 A1
(43) Pub. Date: Jan. 22, 2026

(54) ELECTRONIC COMPONENT TESTING APPARATUS AND TESTING METHOD THEREOF

(71) Applicant: CHROMA ATE INC., Taoyuan City (TW)

(72) Inventors: I-Ching Tsai, Taoyuan City (TW); Chin-Yi Ou Yang, Taoyuan City (TW); Chien-Ming Chen, Taoyuan City (TW); Xin-Yi Wu, Taoyuan City (TW); Yun-Jui Cheng, Taoyuan City (TW); Sung-Fu Hung, Taoyuan City (TW)

(73) Assignee: CHROMA ATE INC., Taoyuan City (TW)

(21) Appl. No.: 19/246,537

(22) Filed: Jun. 23, 2025

(30) Foreign Application Priority Data
Jul. 19, 2024 (TW) 113127229

(51) Int. Cl. G01R 31/28

(52) U.S. Cl. CPC G01R 31/2863; G01R 31/2867

(57) ABSTRACT

An electronic component testing apparatus includes a controller, a transferring device, a testing socket, a workpress, and a testing board. The testing socket loads an electronic component. The controller is electrically connected to the transferring device, the workpress, and the testing board. In response to the transferring device transferring the testing socket to a testing area, the controller controls the workpress to press against the testing socket, and controls a locking mechanism of the workpress to lock the testing socket. In response to the locking mechanism locking the testing socket, the controller controls the workpress to move the testing socket on the testing board.

### CROSS-REFERENCE TO RELATED APPLICATION

This non-provisional application claims priority under 35 U.S.C. § 119(a) to patent application No. 113127229 filed in Taiwan, R.O.C. on Jul. 19, 2024, the entire contents of which are hereby incorporated by reference.

### BACKGROUND

### Technical Field

The present disclosure relates to an electronic component testing apparatus and a testing method thereof.

### Related Art

In an existing electronic component testing apparatus, common ways to transfer an untested electronic component include the following steps: transferring the untested electronic component to a testing area by using a transferring shuttle, where the testing area is provided with at least a testing socket and a workpress, and many devices are even provided with a pick-and-place device; then, moving the electronic component from the transferring shuttle to the testing socket; and finally, testing the electronic component. After the test is completed, the tested electronic component is moved from the testing socket to the transferring shuttle; and then, the transferring shuttle transfers the electronic component to be tested to a loading and unloading area.

### SUMMARY

However, in an electronic component testing apparatus, when a testing subject object is to be replaced, such as replacing a chip with a different design specification, the whole apparatus needs to be shut down to replace the testing socket and related components due to the testing socket fixed on the testing machine, which will affect a productivity utilization rate of the apparatus. In addition, during regular cleaning and maintenance, the testing socket needs to be removed for cleaning and maintenance, which is time-consuming and labor-intensive.

In another aspect, the electronic component must be moved at least four times in the aforementioned way of transferring the untested electronic component. That is, the untested electronic component is moved to the transferring shuttle by using a robotic arm in a loading and unloading area (first move), and then the untested electronic component is moved from the transferring shuttle to the testing socket (second move). After the test is completed, the tested electronic component is moved from the testing socket onto the transferring shuttle (third move). Then, after the transferring shuttle transfers the tested electronic component to the loading and unloading area, the robotic arm removes the tested electronic component from the transferring shuttle (fourth move). However, excessive times of moving not only affects the testing efficiency of the entire apparatus, but also poses a relatively high risk of collision or falling in a moving process.

In view of this, embodiments of the present disclosure provide an electronic component testing apparatus and a testing method thereof.

According to some embodiments, an electronic component testing apparatus includes a controller, a transferring device, a testing socket, a workpress, and a testing board. The transferring device is electrically connected to the controller. The testing socket is configured to load an electronic component. The workpress electrically connected to the controller includes a locking mechanism. In response to the transferring device transferring the testing socket to a testing area, the controller controls the workpress to press against the testing socket, and controls the locking mechanism to lock the testing socket. In addition, the testing board is electrically connected to the controller. In response to the locking mechanism locking the testing socket, the controller controls the workpress to move the testing socket onto the testing board.

In another aspect, according to some embodiments, an electronic component testing method includes: a transferring step, a pressing step, a continuous step, and a testing step.

In the transferring step, a testing socket is transferred to a testing area by a transferring device, wherein the testing socket is configured to load an electronic component.

In the pressing against step, a workpress is pressed against the testing socket, and the testing socket is locked to the workpress through a locking mechanism of the workpress.

In the continuous step, the testing socket is continuously locked to the workpress, and the workpress is controlled to move the testing socket to be in electrical contact with a testing board.

In the testing step, the electronic component is tested.

To sum up, according to some embodiments, since the electronic component is moved together with the testing socket in the testing and transferring operation of the electronic component testing apparatus, the number of times that the electronic component is moved can be reduced. In addition, the electronic component can be protected by the testing socket throughout the operation process, thereby lowering the risk of collision or falling. In some embodiments, the electronic component testing apparatus can allow replacement of the testing socket as needed without requiring shutdown, thereby enhancing operational convenience and facilitating equipment cleaning.

### BRIEF DESCRIPTION OF THE DRAWINGS

FIG. 1 depicts a block diagram of a control system of an electronic component testing apparatus according to some embodiments;

FIG. 2 depicts a partial schematic diagram of an electronic component testing apparatus according to some embodiments, showing that a workpress and a testing board are in a testing area, a pick-and-place device is in a loading and unloading area, with a dotted chain line marking the testing area and the loading and unloading area, a dashed line representing that a transferring device is in the loading and unloading area, and a solid line representing that the transferring device is in the testing area;

FIG. 3 depicts a partial schematic diagram of a workpress according to some embodiments;

FIG. 4A depicts a partial cross-sectional view (I) of the position of area A marked in FIG. 2 according to one embodiment, showing that when a lifting slider is in a release position, locking sliders retracts into hook portions, respectively;

FIG. 4B depicts a partial cross-sectional view (II) of the position of area A marked in FIG. 2 according to one embodiment, showing that when a lifting slider is in a locking position, locking sliders protruding outward from hook portions are in locking grooves, respectively;

FIG. 5 depicts a partial cross-sectional view of the position of area A marked in FIG. 2 according to another embodiment, showing that a locking pin of a testing socket is inserted into a horizontal slider, with a solid line representing that the horizontal slider is in a release position, and a dashed line representing that the horizontal slider is in a locking position;

FIG. 6 depicts a three-dimensional diagram of a horizontal slider according to some embodiments;

FIG. 7A depicts a partial cross-sectional view (I) of an electronic component testing apparatus according to some embodiments, showing that in a testing area, a workpress is controlled to move in a descending direction or in an ascending direction;

FIG. 7B depicts a partial cross-sectional view (II) of an electronic component testing apparatus according to some embodiments, showing a state where a workpress is pressed against a testing socket and the testing socket is locked to the workpress;

FIG. 7C depicts a partial cross-sectional view (III) of an electronic component testing apparatus according to some embodiments, showing that a movement of a workpress causes a testing socket to move in unison therewith in a descending direction or an ascending direction;

FIG. 7D depicts a partial cross-sectional view (IV) of an electronic component testing apparatus according to some embodiments, showing that a testing socket is in electrical contact with a testing board; and

FIG. 8 depicts a partial cross-sectional view (V) of an electronic component testing apparatus according to some embodiments, showing that in a loading and unloading area, a pick-and-place device ascends and descends in a double-headed arrow direction to pick and place an electronic component.

### DETAILED DESCRIPTION

The terms used in the following embodiment related to connections may be physical connections or direct or indirect connections between solid components, unless specifically specified as electrical connections. In addition, the schema of the present disclosure is only used as a schematic illustration, and may not be drawn to scale, and all details may not be fully presented in the schema, which is hereby stated in advance.

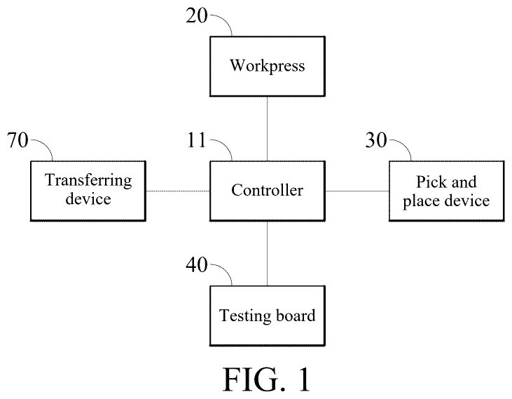

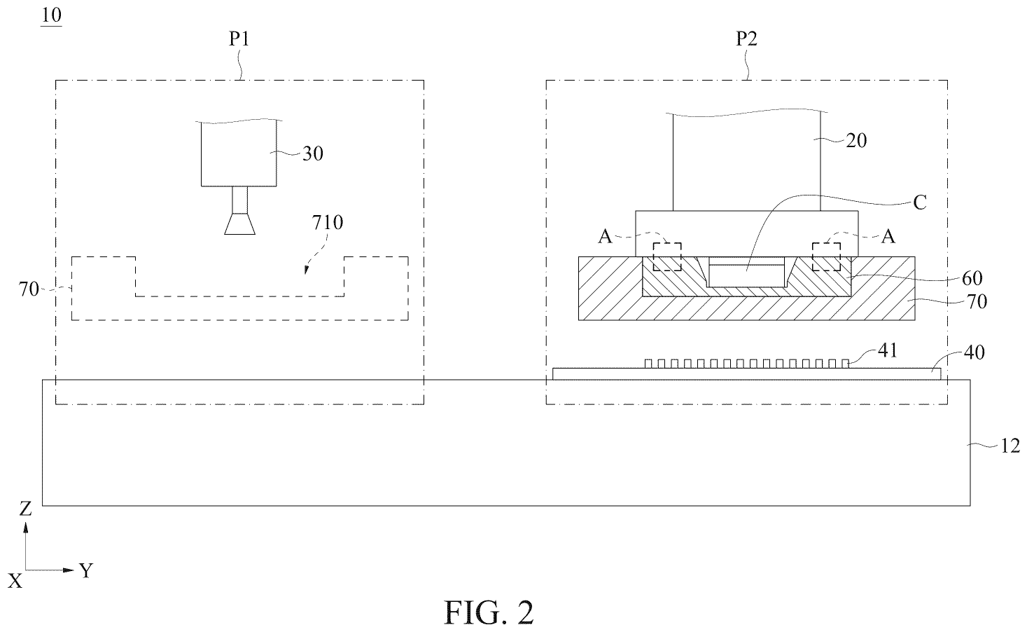

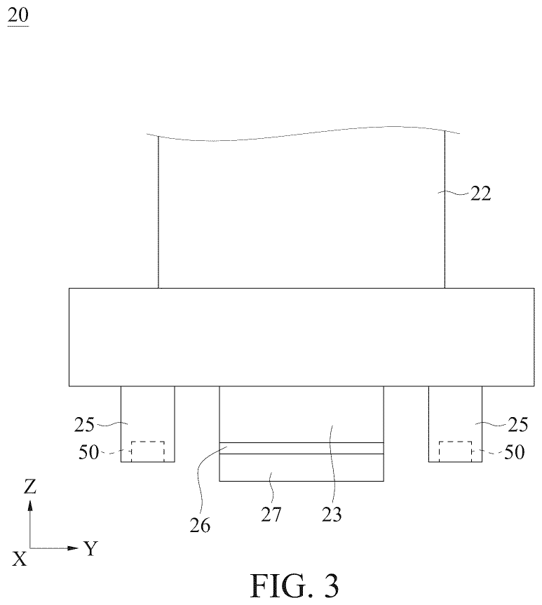

Referring to FIG. 1, FIG. 2, and FIG. 3, FIG. 1 depicts a block diagram of a control system of an electronic component testing apparatus 10 according to some embodiments; FIG. 2 depicts a partial schematic diagram of an electronic component testing apparatus 10 according to some embodiments, showing that a workpress 20 and a testing board 40 are in a testing area P2, a pick-and-place device 30 is in a loading and unloading area P1, with a dotted chain line marking the testing area P2 and the loading and unloading area P1, a dashed line representing that a transferring device 70 is in the loading and unloading area P1, and a solid line representing that the transferring device 70 is in the testing area P2; and FIG. 3 depicts a partial schematic diagram of a workpress 20 according to some embodiments.

Referring to FIG. 1, FIG. 2, and FIG. 3, an electronic component testing apparatus 10 includes the controller 11, the transferring device 70, the testing socket 60, the workpress 20, and the testing board 40. Referring to FIG. 1, the controller 11 is electrically connected to the transferring device 70, the workpress 20, and the testing board 40. Referring to FIG. 2, the controller 11 controls the transferring device 70 to transfer between the loading and unloading area P1 and the testing area P2. The testing socket 60 is configured to load an electronic component C. The transferring device 70 is configured to transfer the testing socket 60 between the loading and unloading area P1 and the testing area P2. The transferring device 70 has a loading groove 710 to accommodate the testing socket 60. In addition, the testing board 40 is disposed below the workpress 20.

Referring to FIG. 2 and FIG. 3, when the transferring device 70 transfers the testing socket 60 to the testing area P2, the controller 11 controls the workpress 20 to press against the testing socket 60, and controls a locking mechanism 50 of the workpress 20 to lock the testing socket 60. In addition, when the testing socket 60 has been locked through the locking mechanism 50, the controller 11 controls the workpress 20 to move the testing socket 60 onto the testing board 40. The “moving the testing socket 60 to the testing board 40” includes that the testing socket 60 is located on the testing board 40 but has not yet electrically contacted the testing board, and the testing socket 60 is in electrical contact with the testing board 40. In some embodiments, the transferring device 70 is moved to a position between the workpress 20 and the testing board 40. In some embodiments, in response to the testing socket 60 being continuously locked through the locking mechanism 50, the controller 11 controls the workpress 20 to move the testing socket 60 and the testing socket 60 electrically contacts the testing board 40.

In some embodiments, an electronic component C may be a chip package or an unpackaged die, for example but not limited to a memory chip, a logic chip, an image sensing chip, etc. In some embodiments, the testing socket 60 is used to provide an electrical interface, so that the electronic component C can be electrically connected to the testing board 40 for testing. Referring to FIG. 2, the electrical interface includes the probes (not shown) disposed on the testing socket 60, which are configured to electrically contact the contact points of the electronic component C, and the probes 41 disposed on the testing board 40, which are configured to electrically contact the contact points disposed on the surface of the testing socket 60 that faces and contacts the testing board 40. In some embodiments, the electronic component testing apparatus 10 includes a base 12 and other members. These other members may include but not limited to a pick-and-place device 30, a support plate, a T-bar, and a damper. The transferring device 70, the workpress 20, the testing board 40, and these other members are installed in different areas of the base 12. For example, the testing area P2 of the base 12 is provided with the workpress 20 and the testing board 40, and the electronic component C is tested in the testing area P2. The loading and unloading area P1 of the base 12 is provided with the pick-and-place device 30. The pick-and-place device 30 is electrically connected to the controller 11. The pick-and-place device 30 is configured to pick and place the electronic components C onto the testing socket 60. In addition, the testing socket 60 may be picked or be placed in the transferring device 70 in the loading and unloading area P1.

Since the electronic component C is moved together with the testing socket 60 in the testing and transferring operation of the electronic component testing apparatus 10, the number of times that the electronic component C is moved can be reduced. In addition, the electronic component C can be protected by the testing socket 60 throughout the operation process, hereby lowering the risk of collision or falling. Moreover, the electronic component testing apparatus 10 can allow replacement of the testing socket as needed without requiring shutdown, thereby enhancing operational convenience and facilitating equipment cleaning.

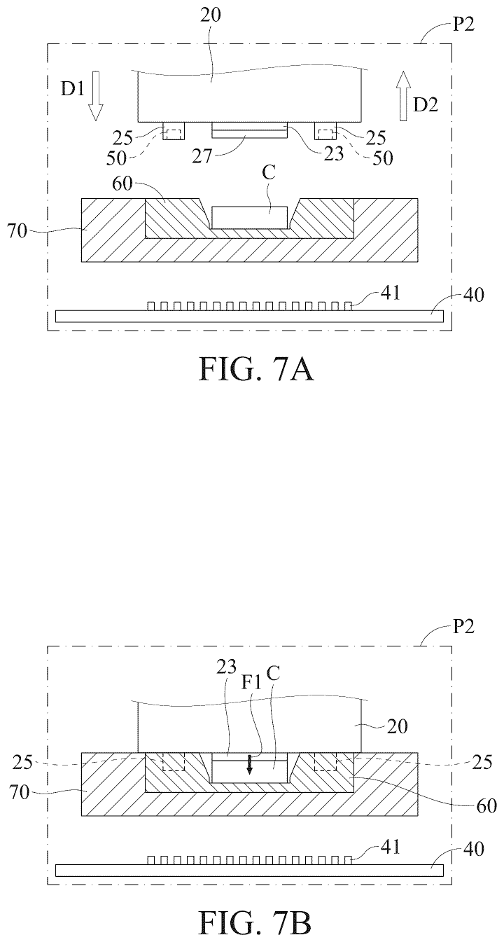

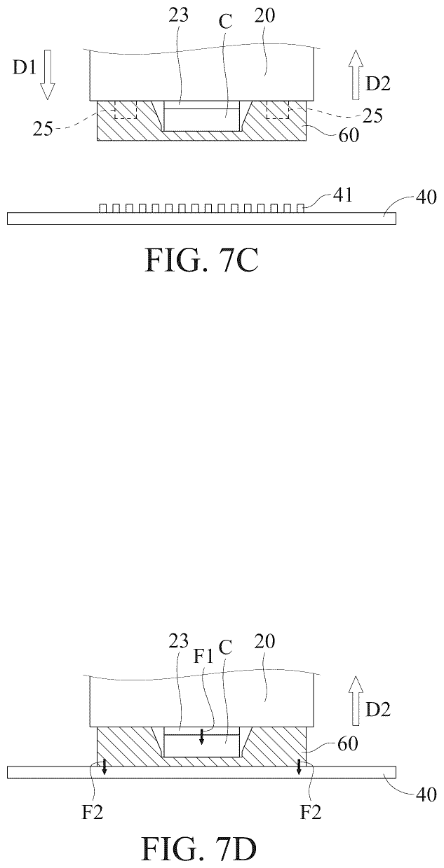

Referring to FIG. 1, FIG. 3 and FIG. 7D, FIG. 7D depicts a partial cross-sectional view (IV) of an electronic component testing apparatus 10 according to some embodiments, showing that a testing socket 60 is in electrical contact with a testing board 40. In some embodiments, the workpress 20 further includes a first pressing force generating device 23 and a second pressing force generating device 22. The first pressing force generating device 23 is electrically connected to the controller 11. The controller 11 controls the first pressing force generating device 23 to apply a first pressing force F1 to the electronic component C (see FIG. 7D), where the first pressing force F1 is sufficient for the electronic component C electrically contacting the electrical interface of the testing socket 60. The second pressing force generating device 22 is electrically connected to the controller 11. The controller 11 controls the second pressing force generating device 22 to apply a second pressing force F2 to the testing socket 60 (see FIG. 7D), where the second pressing force F2 is sufficient for the testing socket 60 electrically contacting the testing board 40. Therefore, the step of applying the first pressing force F1 is for ensuring that the electronic component C is in full electrical contact with the probes in the testing socket 60, while the step of applying the second pressing force F2 is for ensuring that the testing socket 60 is in full electrical contact with the testing board 40.

In some embodiments, after the testing socket 60 is locked through the locking mechanism 50, the first pressing force generating device 23 generates the first pressing force F1. In some embodiments, when controlling the locking mechanism 50 to lock the testing socket 60, the controller 11 also controls the first pressing force generating device 23 to apply the first pressing force F1 to the electronic component C. After the controller 11 controls the workpress 20 to move the testing socket 60 onto the testing board 40, the controller 11 controls the second pressing force generating device 22 to apply the second pressing force F2 to the testing socket 60. In some embodiments, after the controller 11 controls the workpress 20 to move the testing socket 60 onto the testing board 40, the first pressing force generating device 23 generates the first pressing force F1 and the second pressing force generating device 22 generates the second pressing force F2.

Referring to FIG. 3, in some embodiments, the workpress 20 further includes a hook portion 25, a heat transfer interface material 27, and a temperature control device 26. One end of the hook portion 25 is provided with the locking mechanism 50. The temperature control device 26 may be a high temperature generator or a low temperature generator for heating or cooling the electronic component C. The high temperature generator or the low temperature generator may include but not limited to a resistive heat source, a thermoelectric cooling module (TEC), or other devices using temperature control fluid. In one embodiment, the temperature control device 26 can be used as a condenser, such as, a circuitous flow channel with refrigerant circulating in the workpress 20, and the refrigerant may be liquid nitrogen, ethylene glycol, halogenated hydrocarbons, ammonia, sulfur dioxide, methane or other cryogenic fluids. The heat transfer interface material 27 may be, but is not limited to, a heat sink pad, a phase change material, a phase change metal sheet, thermal grease, or silicone grease. The heat transfer interface material 27 is disposed on a contact surface between the workpress 20 and the electronic component C. The temperature control device 26 heats or cools the electronic component C through the heat transfer interface material 27. The heat transfer interface material 27 is adapted to fill an air gap between the workpress 20 and the electronic component C, hereby reducing the contact thermal resistance and improving the heat conduction performance.

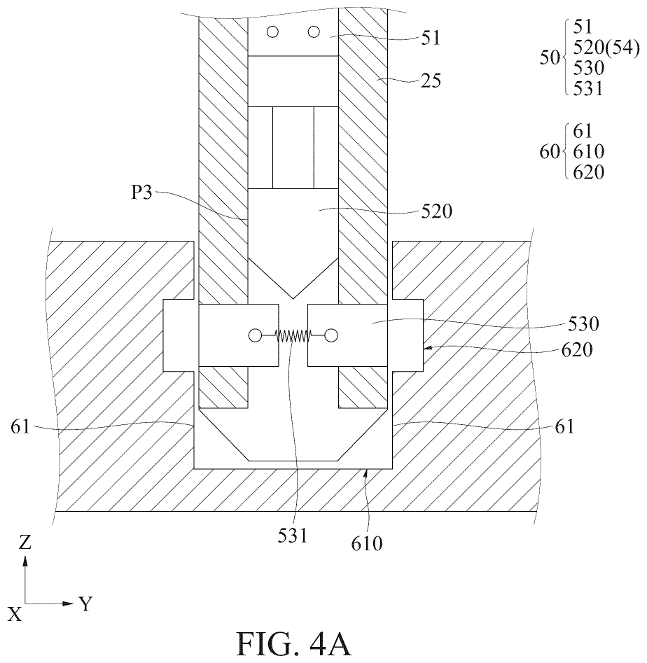

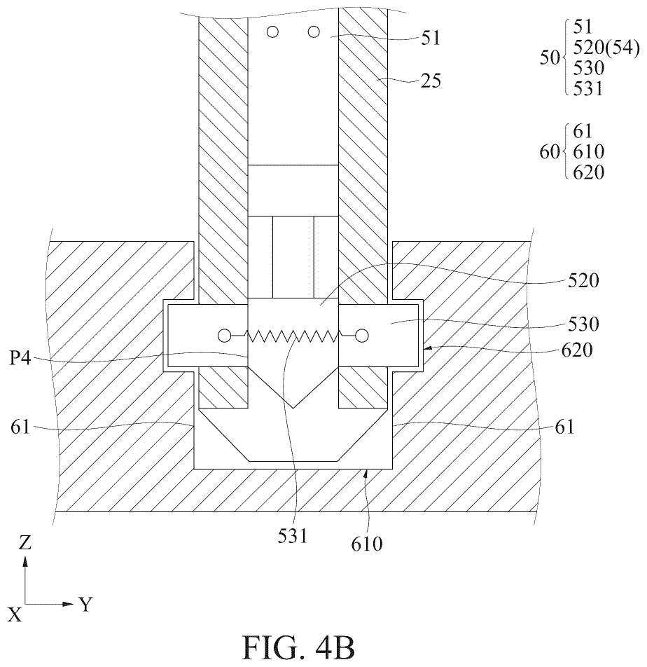

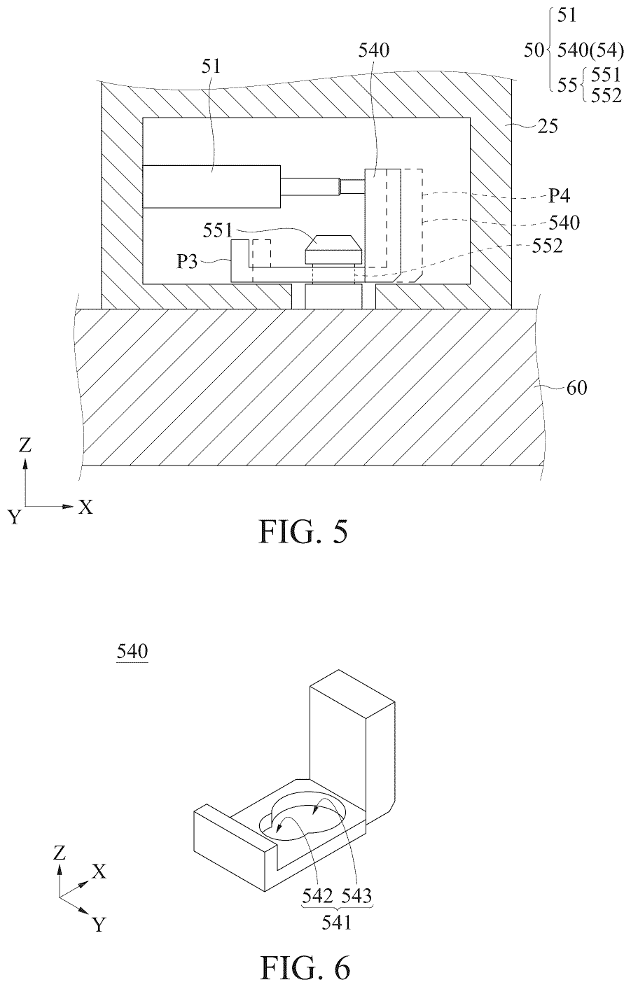

Referring to FIG. 4A, FIG. 4B, and FIG. 5, FIG. 4A depicts a partial cross-sectional view (I) of the position of area A marked in FIG. 2 according to one embodiment, showing that when a lifting slider 520 is in a release position P3, locking sliders 530 retract into hook portions 25, respectively; FIG. 4B depicts a partial cross-sectional view (II) of the position of area A marked in FIG. 2 according to one embodiment, showing that when a lifting slider 520 is in a locking position P4, locking slider 530 protruding outward from hook portions 25 are in locking grooves 620, respectively; and FIG. 5 depicts a partial cross-sectional view of the position of area A marked in FIG. 2 according to another embodiment, showing that a locking pin 55 of a testing socket 60 is inserted into a horizontal slider 540, with a solid line representing that the horizontal slider 540 is in a release position P3, and a dashed line representing that the horizontal slider 540 is in a locking position P4.

Referring to FIG. 2, FIG. 4A, FIG. 4B, and FIG. 5, in some embodiments, the locking mechanism 50 includes a moving element 54 and an actuator 51, where the actuator 51 is electrically connected to the controller 11. The actuator 51 may be, but not limited to, a pneumatic cylinder, a linear motor, or other mechanisms or devices that can provide reciprocating linear motion. In addition, the moving element 54 is driven by the actuator 51 to slide between the release position P3 and the locking position P4 inside the hook portion 25. After the controller 11 controls the workpress 20 to press against the testing socket 60, the controller 11 controls the actuator 51 to drive the moving element 54 to slide from the release position P3 to the locking position P4 to lock the testing socket 60. After the controller 11 controls the workpress 20 to place the testing socket 60 into the transferring device 70, the controller 11 controls the actuator 51 to drive the moving element 54 to slide from the locking position P4 to the release position P3 to release the testing socket 60. The locking mechanism 50 may be, but is not limited to, two embodiments shown in FIG. 4A, FIG. 4B, and FIG. 5.

Referring to FIG. 4A and FIG. 4B, in some embodiments, the testing socket 60 has an insertion slot 610, where the side wall 61 of the insertion slot 610 is disposed the locking groove 620. The opening of the locking groove 620 is toward the hook portion 25. The moving element 54 is the lifting slider 520. The locking mechanism 50 further includes locking sliders 530. The locking slider 530 is disposed at one end of the hook portion 25. When the workpress 20 is pressed against the testing socket 60, the hook portion 25 is inserted into the insertion slot 610. In addition, the lifting slider 520 and the locking slider 530 move in a first direction and a second direction, respectively, where the first direction is substantially perpendicular to the second direction. Referring to FIG. 4A, the first direction is the Z-axis direction and the second direction is the Y-axis direction. When the lifting slider 520 is positioned in the release position P3, the hook portion 25 is not engaged within the insertion slot 610 and can be movably released from the insertion slot 610. Referring to FIG. 4B, one end of the hook portion 25 is inserted into the insertion slot 610 and the lifting slider 520 is in the locking position P4, the locking slider 530 is engaged within the insertion slot 610, and the testing socket 60 is locked to the workpress 20. In some embodiments, one locking slider 530 corresponds to one locking groove 620, and each locking slider 530 is able to selectively slide into or out of the corresponding locking groove 620. The opposite two locking sliders 530 are connected to each other by the resilient element 531. In some embodiments, the resilient element 531 provides a force to make the locking sliders 530 connected at two ends approach each other. The resilient element 531 may be, but is not limited to, a spring. Specifically, referring to FIG. 4A, when the lifting slider 520 is positioned in the release position P3, the resilient element 531 provides a resilient restoring force to make the locking slider 530 disengaged from the locking groove 620 and back into the hook portion 25. Referring to FIG. 4B, when the lifting slider 520 is positioned in the locking position P4, the resilient element 531 between two opposite locking sliders 530 is pushed open by the lifting slider 520, and the locking sliders 530 protrude from the hook portion 25 and are engaged with the locking groove 620.

Referring to FIG. 5 and FIG. 6, FIG. 6 depicts a three-dimensional diagram of a horizontal slider 540 according to some embodiments. In some embodiments, the moving element 54 is a horizontal slider 540. The testing socket 60 has locking pins 55, and the horizontal slider 540 is disposed locking holes 541. Each of the locking pin 55 corresponds to one of the locking holes 541 of the horizontal slider 540. The locking pin 55 is configured to insert into the corresponding locking hole 541. The locking pin 55 has a head portion 551 and a neck portion 552, where the head portion 551 is the free end of the locking pin 55. The head portion 551 extends towards the hook portion 25. The neck portion 552 is the fixed end of the locking pin 55 and is connected to the base of the testing socket 60. Referring to FIG. 6, the locking hole 541 has a locking section 542 and an assembly section 543. The locking section 542 is in communication with the assembly section 543 to form a droplet-shaped opening. The opening of the assembly section 543 is sufficient to accommodate the head portion 551 of the locking pin 55, and the opening of the locking section 542 is sufficient to accommodate the neck portion 552 of the locking pin 55. Referring to FIG. 5, along the X axis, the width of the head portion 551 is substantially greater than the width of the neck portion 552. The horizontal slider 540 is driven by the actuator 51 to slide between the release position P3 and the locking position P4. Specifically, when the workpress 20 is pressed against the testing socket 60, the locking pin 55 of the testing socket 60 is at the assembly section 543 of the locking hole 541. At this time, the controller 11 controls the actuator 51 to drive the moving element 54 to slide to the locking position P4. As the result, the locking hole 541 is able to be engaged with the locking pin 55. In some embodiments, when the horizontal slider 540 is positioned in the release position P3, the locking pin 55 at the assembly section 543 is able to be movably released from the locking hole 541. When the horizontal slider 540 is positioned in the locking position P4, the locking pin 55 is at the locking section 542 of the locking hole 541, and the locking pin 55 is engaged with the locking hole 541.

Referring to FIG. 7A to FIG. 7C, FIG. 7A depicts a partial cross-sectional view (I) of an electronic component testing apparatus 10 according to some embodiments, showing that in a testing area P2, a workpress 20 is controlled to move in a descending direction D1 or in an ascending direction D2; FIG. 7B depicts a partial cross-sectional view (II) of an electronic component testing apparatus 10 according to some embodiments, showing a state where a workpress 20 is pressed against a testing socket 60 and the testing socket 60 is locked to the workpress 20; and FIG. 7C depicts a partial cross-sectional view (III) of an electronic component testing apparatus 10 according to some embodiments, showing that a movement of a workpress 20 causes a testing socket 60 to move in unison therewith in a descending direction D1 or an ascending direction D2.

In another aspect, the present disclosure provides an electronic component testing method (referring as the “testing method” hereafter), which is executed by the electronic component testing apparatus 10. It should be noted that in the testing method described in the following embodiment, steps may be performed in any order without deviating from the principle of the present disclosure, unless the time or operation order is explicitly stated.

This testing method includes the following steps: a transferring step, a pressing step, a continuous step, and a testing step.

In the transferring step, the testing socket 60 is transferred to the testing area P2 by the transferring device 70, wherein the testing socket 60 is configured to load the electronic component C.

In the pressing step, the workpress 20 is pressed against the testing socket 60, and the testing socket 60 is locked to the workpress 20 through the locking mechanism 50 of the workpress 20.

In the continuous locking step, the testing socket 60 is continuously locked to the workpress 20, and the workpress 20 is controlled to move the testing socket 60 to electrically contact the testing board 40.

In the testing step, the electronic component C is tested.

Referring to FIG. 7A to FIG. 7D, in some embodiments, the partial cross-sectional views of the electronic component testing apparatus 10 when performing the transferring step, the pressing step, the continuous locking step, and the testing step are shown in FIG. 7A, FIG. 7B, FIG. 7C, and FIG. 7D, respectively.

Please refer to FIG. 7A to FIG. 7D in order. For example, the electronic component testing apparatus 10 is operated to test the electronic component C. Referring to FIG. 7A, in the transferring step, the transferring device 70 transfers the testing socket 60 to the testing area P2, and the untested electronic component C has been placed into the testing socket 60 in advance. In the pressing step, the workpress 20 is controlled to move in the descending direction D1 in FIG. 7A until the workpress 20 is pressed against the testing socket 60, so that the testing socket 60 is locked to the workpress 20, as shown in FIG. 7B. Next, referring to FIG. 7C, in the continuous locking step, as the testing socket 60 is continuously locked to the workpress 20, the workpress 20 is controlled to move in the ascending direction D2 in FIG. 7C until the workpress 20 is detached from the transferring device 70. Then, the transferring device 70 completely exits the testing area P2. The workpress 20 moves in the descending direction D1 in FIG. 7C, and the testing socket 60 is in electrical contact with the testing board 40, as shown in FIG. 7D. Finally, in the testing step, the controller 11 tests the electronic component C through the testing board 40.

Referring to FIG. 4A, FIG. 4B, and FIG. 5, in some embodiments, in the pressing step, the moving element 54 of the locking mechanism 50 is driven by the actuator 51 to slide from the release position P3 to the locking position P4, and the testing socket 60 is locked to the workpress 20.

Referring to FIG. 7D, in some embodiments, the continuous locking step includes the steps of: applying the first pressing force F1; applying the second pressing force F2; and initiating the test.

In the step of applying the first pressing force F1, the first pressing force F1 is applied by the workpress 20 to the electronic component C.

In the step of applying the second pressing force F2, the second pressing force F2 is applied by the workpress 20 to the testing socket 60.

In the step of initiating the test, the test of the electronic component C is initiated.

Specifically, the first pressing force F1 is generated by the first pressing force generating device 23. The second pressing force F2 is generated by the second pressing force generating device 22. In addition, the step of applying the first pressing force F1 can ensure full electrical contact between the untested electronic component C and the probes in the testing socket 60. The step of applying the second pressing force F2 can ensure full electrical contact between the testing socket 60 and the testing board 40. After full electrical contact is established among the untested electronic component C, the testing socket 60, and the testing board 40, the step of initiating the test of the electronic component C is performed.

In some embodiments, the first pressing force F1 and the second pressing force F2 are respectively applied by the workpress 20 only when the testing socket 60 has been locked to the workpress 20 and positioned on the testing board 40. In some embodiments, the first pressing force F1 and the second pressing force F2 are applied in separate stages or in succession (e.g., successively applied in the same stage). According to the inventor's knowledge, when the electronic component testing apparatus 10 conducts the chip test, in order to ensure full electrical contact of all contact points on the chip, the electronic component testing apparatus 10 apply at least 300 Kgf pressing force, and the pressing force is so large that it is likely to cause deformation of the electronic component C, the testing socket 60 or the testing board 40. In this embodiment, the first pressing force F1 is balanced internally between the workpress 20 and the testing socket 60 through the locking mechanism 50, such that no additional load is applied to the testing board 40. Accordingly, the testing board 40 only needs to bear the second pressing force F2, rather than the total pressing force. Therefore, deformation-induced wear of the electronic component C and the test board 40 during the testing process can be reduced.

In addition, referring to FIG. 7B and FIG. 7D, in some embodiments, after the pressing step, the testing method includes: the first pressing force F1 being applied by the workpress 20 to the electronic component C. Moreover, in the continuous locking step, the second pressing force F2 is applied by the workpress 20 to the testing socket 60, and the testing socket 60 electrically contacts the testing board 40. For example, referring to FIG. 7B, when the testing socket 60 has been locked to the workpress 20, the workpress 20 firstly applies the first pressing force F1 to the electronic component C. At this time, the first pressing force F1 will balance the internal force between the workpress 20 and the testing socket 60. Next, referring to FIG. 7D, in the continuous locking step, the testing socket 60 is positioned on the testing board 40, then the workpress 20 applies the second pressing force F2 to the testing socket 60. In this embodiment, the first pressing force F1 and the second pressing force F2 are applied by the workpress 20 in separate stages, thereby lowering the risk that the excessive pressing force damages a machine structure.

In some embodiments, after the testing step, the testing method further includes a releasing step.

In the releasing step, the testing socket 60 is released through the locking mechanism 50 after the workpress 20 is moved to place the testing socket 60 into the transferring device 70.

Please refer to FIG. 7D to FIG. 7A in order. Referring to FIG. 7D, after the testing step, the electronic component C has been tested, and the workpress 20 is controlled to move in the ascending direction D2 in FIG. 7D, so that the testing socket 60 is detached from the testing board 40, as shown in FIG. 7C. At this time, the testing socket 60 remains locked to the workpress 20. Next, the workpress 20 is controlled to ascend continuously until the transferring apparatus 70 is able to move into the testing area P2. Referring to FIG. 7B, after the transferring device 70 is positioned in the testing area P2, the workpress 20 descends to place the testing socket 60 into the transferring device 70. In the releasing step, the testing socket 60 is released through the locking mechanism 50 after the testing socket 60 has been placed into the transferring device 70. After that, the workpress 20 continuously moves in the ascending direction D2 to detach from the testing socket 60, as shown in FIG. 7A. Finally, the transferring device 70 transfers the testing socket 60 and the tested electronic component C from the testing area P2 towards the loading and unloading area P1.

Referring to FIG. 4A, FIG. 4B, and FIG. 5, in some embodiments, in the releasing step, the moving element 54 of the locking mechanism 50 is driven by the actuator 51 to slide from the locking position P4 toward the release position P3 to release the testing socket 60.

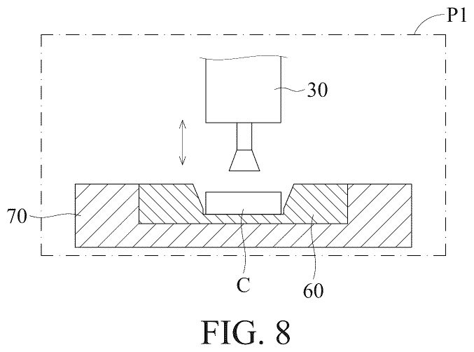

Referring to FIG. 8, FIG. 8 depicts a partial schematic diagram (V) of an electronic component testing apparatus 10 according to some embodiments, showing that in a loading and unloading area P1, a pick-and-place device 30 ascends and descends in a double-headed arrow direction to pick and place an electronic component C. In some embodiments, before the transferring step, the testing method further includes a placement step.

In the placement step: the pick-and-place device 30 places the untested electronic component C into the testing socket 60, and the transferring device 70 transfers the untested electronic component C out of the loading and unloading area P1.

In some embodiments, both the untested electronic component C and the testing socket 60 are placed into the transferring device 70 in the loading and unloading area P1. The transferring device 70 transfers the untested electronic component C and the testing socket 60 from the loading and unloading area P1 to the testing area P2. After that, the steps described in the foregoing embodiments are performed in order to complete the test of the electronic component C.

Referring to FIG. 8, in some embodiments, after the testing step, the testing method further includes a picking step.

In the picking step, the tested electronic component C is picked from the testing socket 60 by the pick-and-place device 30 after the transferring device 70 transfers the testing socket 60 from the testing area P2 to the loading and unloading area P1.

To sum up, according to any embodiment, since the electronic component C is moved together with the testing socket 60 in the testing and transferring operation of the electronic component testing apparatus 10, the number of times that the electronic component C is moved can be reduced. In addition, the electronic component C can be protected by the testing socket 60 throughout the operation process, hereby lowering the risk of collision or falling. Moreover, the electronic component testing apparatus 10 allows replacement of the testing socket 60 as needed without requiring shutdown, thereby enhancing operational convenience and facilitating equipment cleaning.

What is claimed is:

1. An electronic component testing apparatus, comprising:
a controller;
a transferring device, electrically connected to the controller;
a testing socket, configured to load an electronic component;
a workpress, electrically connected to the controller, and comprising a locking mechanism, wherein in response to the transferring device transferring the testing socket to a testing area, the controller controls the workpress to press against the testing socket, and the controller controls the locking mechanism to lock the testing socket; and
a testing board, electrically connected to the controller, wherein in response to the locking mechanism locking the testing socket, the controller controls the workpress to move the testing socket onto the testing board.

2. The electronic component testing apparatus according to claim 1, wherein the locking mechanism comprises:
an actuator, electrically connected to the controller; and
a moving element, connected to the actuator and controlled by the actuator to slide between a release position and a locking position, wherein
in response to the workpress pressing against the testing socket, the controller controls the actuator to drive the moving element to slide from the release position to the locking position to lock the testing socket.

3. The electronic component testing apparatus according to claim 2, wherein the workpress comprises a hook portion, the testing socket comprises an insertion slot, the moving element is a lifting slider, and the locking mechanism further comprises:
a locking slider, disposed at one end of the hook portion, wherein in response to one end of the hook portion being inserted into the insertion slot and the lifting slider being in the locking position, the locking slider is engaged within the insertion slot of the testing socket.

4. The electronic component testing apparatus according to claim 2, wherein the testing socket comprises a locking pin; the moving element comprises a locking hole; and in response to the workpress pressing against the testing socket, the controller controls the actuator to drive the moving element to slide to the locking position, and the locking hole is engaged with the locking pin.

5. The electronic component testing apparatus according to claim 1, wherein the workpress comprises:
a first pressing force generating device, electrically connected to the controller, wherein the controller controls the first pressing force generating device to apply a first pressing force on the electronic component; and
a second pressing force generating device, electrically connected to the controller, wherein the controller controls the second pressing force generating device to apply a second pressing force on the testing socket to electrically contact the testing board.

6. An electronic component testing method, comprising:
a transferring step: in which a testing socket is transferred to a testing area by a transferring device, wherein the testing socket is configured to load an electronic component;
a pressing step: in which a workpress is pressed against the testing socket, and the testing socket is locked to the workpress through a locking mechanism of the workpress;
a continuous locking step: in which the testing socket is continuously locked to the workpress, and the workpress is controlled to move the testing socket to electrically contact a testing board; and
a testing step: in which the electronic component is tested.

7. The electronic component testing method according to claim 6, wherein in the pressing step, a moving element of the locking mechanism is driven by an actuator to slide from a release position to a locking position, and the testing socket is locked to the workpress.

8. The electronic component testing method according to claim 6, wherein the continuous locking step comprises:
a first pressing force being applied by the workpress to the electronic component; and
a second pressing force being applied by the workpress to the testing socket.

9. The electronic component testing method according to claim 6, wherein after the pressing step, the electronic component testing method comprises: a first pressing force being applied by the workpress to the electronic component; and
in the continuous locking step, a second pressing force is applied by the workpress to the testing socket, and the testing socket electrically contacts the testing board.

10. The electronic component testing method according to claim 6, wherein after the testing step, the electronic component testing method further comprises:
the locking mechanism releasing the testing socket after the workpress is moved to place the testing socket into the transferring device.
